(19) United States
(12) Patent Application Publication
(10) Pub. No.: US 2014/0209240 A1
(43) Pub. Date: Jul. 31, 2014

(54) VACUUM PROCESSING APPARATUS

(71) Applicant: Disco Corporation, Tokyo (JP)

(72) Inventors: Sakae Matsuzaki, Tokyo (JP); Takatoshi Masuda, Tokyo (JP)

(73) Assignee: Disco Corporation, Tokyo (JP)

(21) Appl. No.: 14/168,190

(22) Filed: Jan. 30, 2014

(30) Foreign Application Priority Data
Jan. 31, 2013 (JP) 2013-016845

(51) Int. Cl. H01L 21/67; H01L 21/677

(52) U.S. Cl. CPC H01L 21/67069; H01L 21/677
USPC 156/345.31

(57) ABSTRACT

A vacuum processing apparatus for processing a workpiece under vacuum. The vacuum processing apparatus includes a housing having a first vacuum chamber for processing the workpiece and a second vacuum chamber partitioned from the first vacuum chamber by a partition wall and communicating with the first vacuum chamber through a communication opening formed in the partition wall, a shutter for closing the communication opening of the partition wall, a gate for closing a workpiece load/unload opening communicating with the second vacuum chamber, a workpiece holding unit provided in the first vacuum chamber for holding the workpiece, a processing unit for processing the workpiece held by the workpiece holding unit, a first evacuating unit for evacuating the first vacuum chamber, and a second evacuating unit for evacuating the second vacuum chamber.

### BACKGROUND OF THE INVENTION

1. Field of the Invention

The present invention relates to a vacuum processing apparatus for performing processing such as plasma processing to a workpiece such as a semiconductor wafer under vacuum.

2. Description of the Related Art

In a semiconductor device fabrication process, a plurality of crossing division lines called streets are formed on the front side of a substantially disk-shaped semiconductor wafer to thereby partition a plurality of regions where a plurality of devices such as ICs and LSIs are respectively formed. The semiconductor wafer is cut along the division lines to thereby divide the regions where the devices are formed from each other, thus obtaining a plurality of individual semiconductor chips. Prior to dividing the semiconductor wafer into the individual devices, the back side of the semiconductor wafer is ground by a grinding apparatus to thereby reduce the thickness of the wafer to a predetermined thickness.

However, when the back side of the wafer is ground as mentioned above, a grinding strain is left on the back side of the wafer, causing a reduction in die strength of each device divided from the wafer. To solve such a problem, there has been proposed a technique of performing plasma etching to the back side of the wafer to thereby remove the grinding strain left on the back side of the wafer and accordingly improve the die strength of each device (see Japanese Patent Laid-open No. 2004-221175, for example).

Further, cutting of the wafer along the streets as mentioned above is usually performed by a cutting apparatus called dicing saw. This cutting apparatus includes a chuck table for holding the wafer as a workpiece, cutting means having a cutting blade for cutting the workpiece held on the chuck table, and feeding means for relatively moving the chuck table and the cutting means, wherein the cutting blade is rotated and the chuck table holding the workpiece is fed to thereby cut the wafer along the division lines.

However, when the wafer is cut by the cutting blade in the cutting apparatus mentioned above, a cutting strain is left on the side surface of each device divided from the wafer, causing a reduction in die strength of each device. To solve such a problem, there has been proposed a technique of performing plasma etching to the back side and side surface of each device after dividing the wafer into the individual devices, thereby removing the grinding strain left on the back side of each device and the cutting strain left on the side surface of each device to accordingly improve the die strength of each device (see Japanese Patent Laid-open No. 2005-252126, for example).

The plasma etching mentioned above is performed by using a plasma etching apparatus including a housing forming a vacuum chamber as a plasma processing chamber, a lower electrode provided in the vacuum chamber and including a workpiece holding portion having an upper surface for holding a workpiece thereon, an upper electrode including a gas discharging portion opposed to the workpiece holding portion of the lower electrode and having a plurality of discharge ports for discharging a plasma generation gas toward the workpiece holding portion, and a gate for closing a workpiece load/unload opening formed in a side wall of the housing (see Japanese Patent Laid-open No. 2008-28021, for example).

### SUMMARY OF THE INVENTION

In loading the workpiece to the workpiece holding portion of the lower electrode in the plasma etching apparatus mentioned above, the gate is opened and the pressure in the vacuum chamber accordingly becomes an atmospheric pressure. On the other hand, in performing plasma etching to the workpiece held on the workpiece holding portion of the lower electrode, the vacuum chamber must be evacuated. However, considerable time is required to evacuate the vacuum chamber from the atmospheric pressure reached in loading the workpiece to a low pressure of 20 Pa or less, for example, causing a reduction in productivity.

It is therefore an object of the present invention to provide a vacuum processing apparatus which can maintain a vacuum chamber for processing a workpiece in an evacuated condition in loading and unloading the workpiece to and from the vacuum chamber.

In accordance with an aspect of the present invention, there is provided a vacuum processing apparatus for processing a workpiece under vacuum. The apparatus includes: a housing having a first vacuum chamber for processing the workpiece and a second vacuum chamber partitioned from the first vacuum chamber by a partition wall and communicating with the first vacuum chamber through a communication opening formed in the partition wall; shutter means for closing the communication opening of the partition wall; gate means for closing a workpiece load/unload opening formed in a side wall of the housing and communicating with the second vacuum chamber; workpiece holding means provided in the first vacuum chamber for holding the workpiece; processing means for processing the workpiece held by the workpiece holding means; first evacuating means for evacuating the first vacuum chamber; second evacuating means for evacuating the second vacuum chamber; temporary placing means provided in the second vacuum chamber for temporarily placing the workpiece; and workpiece handling means for transferring the workpiece placed on the temporary placing means through the communication opening of the partition wall to the workpiece holding means provided in the first vacuum chamber and also for transferring the workpiece placed on the workpiece holding means through the communication opening of the partition wall to the temporary placing means. The workpiece holding means has a center holding table for holding a central area of the workpiece and elevating means for vertically moving the center holding table. The workpiece handling means has a periphery supporting member for supporting a peripheral area of the workpiece.

Preferably, the periphery supporting member of the workpiece handling means has two supporting portions for supporting the peripheral area of the workpiece, the two supporting portions being spaced a distance larger than the size of the center holding table. Preferably, the workpiece is a semiconductor wafer supported through a dicing tape to an annular frame, the center holding table holding the semiconductor wafer as the central area of the workpiece, the two supporting portions of the periphery supporting member supporting the annular frame as the peripheral area of the workpiece.

In the vacuum processing apparatus according to the present invention, the workpiece holding means provided in the first vacuum chamber includes the center holding table for holding the central area of the workpiece and the elevating means for vertically moving the center holding table. Further, the workpiece handling means has the periphery supporting member for supporting the peripheral area of the workpiece. In loading and unloading the workpiece to and from the first vacuum chamber for processing the workpiece, the first vacuum chamber is maintained in an evacuated condition, so that the processing can be performed at once, thereby improving the productivity.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a sectional view of a plasma etching apparatus as a preferred embodiment of the vacuum processing apparatus according to the present invention;

FIG. 2 is a perspective view of an essential part of workpiece holding means constituting the plasma etching apparatus shown in FIG. 1;

FIG. 3 is a sectional view of the workpiece holding means shown in FIG. 2;

FIG. 4 is a perspective view of workpiece handling means constituting the plasma etching apparatus shown in FIG. 1; and

FIG. 5 is a perspective view showing a condition where a semiconductor wafer as a workpiece is attached to a dicing tape supported to an annular frame.

### DETAILED DESCRIPTION OF THE PREFERRED EMBODIMENT

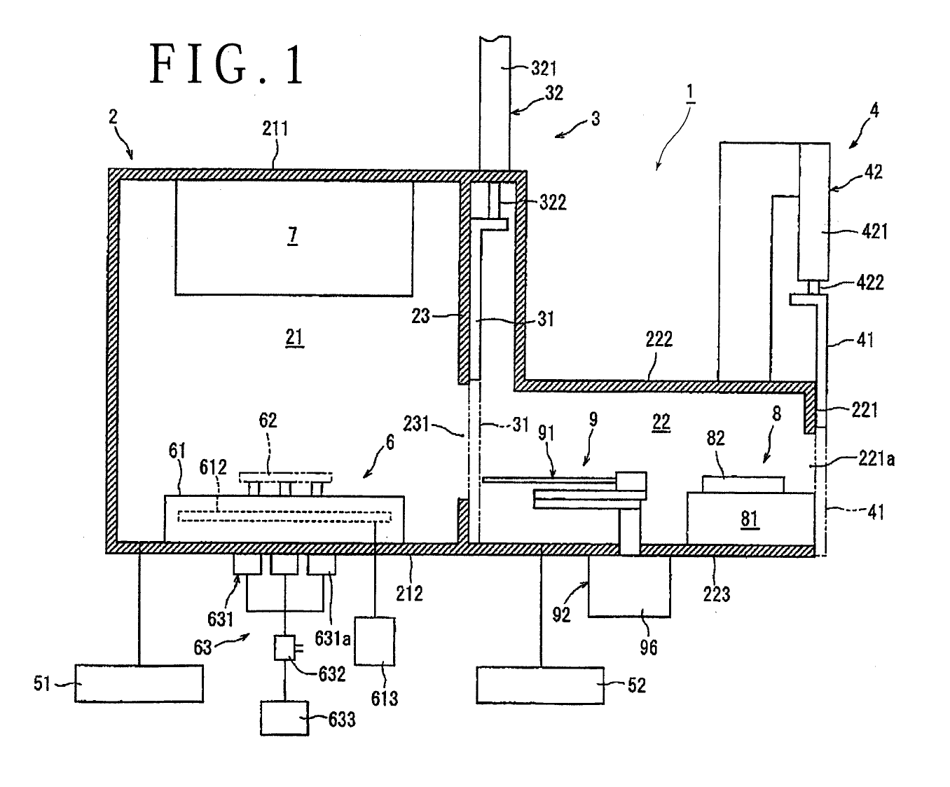

A preferred embodiment of the vacuum processing apparatus according to the present invention will now be described in detail with reference to the attached drawings. FIG. 1 is a sectional view of a plasma etching apparatus 1 as a preferred embodiment of the vacuum processing apparatus according to the present invention.

As shown in FIG. 1, the plasma etching apparatus 1 includes a housing 2 having a first vacuum chamber 21 for plasma-etching a workpiece and a second vacuum chamber 22 for temporarily placing the workpiece. The first vacuum chamber 21 and the second vacuum chamber 22 of the housing 2 are partitioned from each other by a partition wall 23 and are in communication with each other through a communication opening 231 formed in the partition wall 23. A side wall 221 forming the second vacuum chamber 22 of the housing 2 is formed with a workpiece load/unload opening 221a communicating with the second vacuum chamber 22. Preferably, the volume of the second vacuum chamber 22 is smaller than that of the first vacuum chamber 21.

The plasma etching apparatus 1 further includes shutter means 3 for closing the communication opening 231 of the partition wall 23. The shutter means 3 is composed of a shutter 31 provided on the second vacuum chamber 22 side of the partition wall 23 so as to be vertically movable along the partition wall 23 and shutter operating means 32 for vertically operating the shutter 31. The shutter operating means 32 is composed of an air cylinder 321 and a piston rod 322 connected to a piston (not shown) provided in the air cylinder 321. The air cylinder 321 is mounted on an upper wall 211 forming the first vacuum chamber 21 of the housing 2. The front end (lower end as viewed in FIG. 1) of the piston rod 322 is connected to the shutter 31. The shutter means 3 configured above operates in the following manner. When the shutter 31 is moved upward by the shutter operating means 32 to an open position shown by a solid line in FIG. 1, the communication opening 231 of the partition wall 23 is exposed to make the communication between the first vacuum chamber 21 and the second vacuum chamber 22. Conversely, when the shutter 31 is moved downward by the shutter operating means 32 to a closed position shown by a phantom line in FIG. 1, the communication opening 231 of the partition wall 23 is closed to interrupt the communication between the first vacuum chamber 21 and the second vacuum chamber 22.

The plasma etching apparatus 1 further includes gate means 4 for closing the workpiece load/unload opening 221a of the side wall 221 forming the second vacuum chamber 22 of the housing 2. The gate means 4 is composed of a gate 41 provided on the outside of the side wall 221 so as to be vertically movable along the side wall 221 and gate operating means 42 for vertically operating the gate 41. The gate operating means 42 is composed of an air cylinder 421 and a piston rod 422 connected to a piston (not shown) provided in the air cylinder 421. The air cylinder 421 is mounted on an upper wall 222 forming the second vacuum chamber 22 of the housing 2. The front end (lower end as viewed in FIG. 1) of the piston rod 422 is connected to the gate 41. The gate means 4 configured above operates in the following manner. When the gate 41 is moved upward by the gate operating means 42 to an open position shown by a solid line in FIG. 1, the workpiece load/unload opening 221a of the side wall 221 is exposed. Conversely, when the gate 41 is moved downward by the gate operating means 42 to a closed position shown by a phantom line in FIG. 1, the workpiece load/unload opening 221a of the solid wall 221 is closed.

The first vacuum chamber 21 of the housing 2 is in communication with first evacuating means 51, and the second vacuum chamber 22 of the housing 2 is in communication with second evacuating means 52. Accordingly, when the first evacuating means 51 is operated, the first vacuum chamber 21 is evacuated. Similarly, when the second evacuating means 52 is operated, the second vacuum chamber 22 is evacuated.

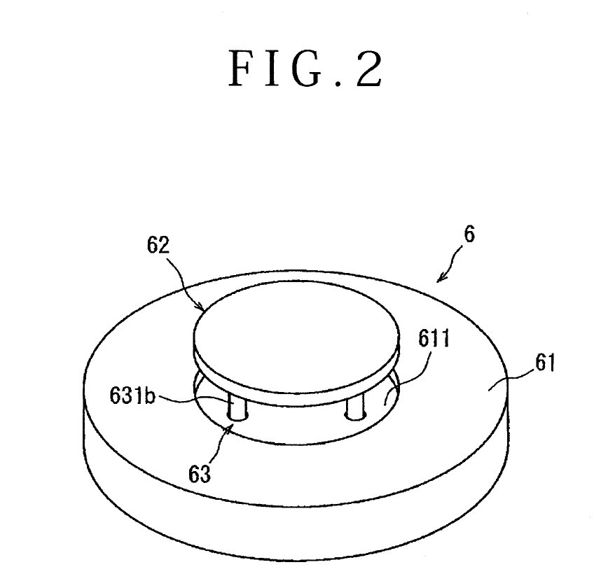

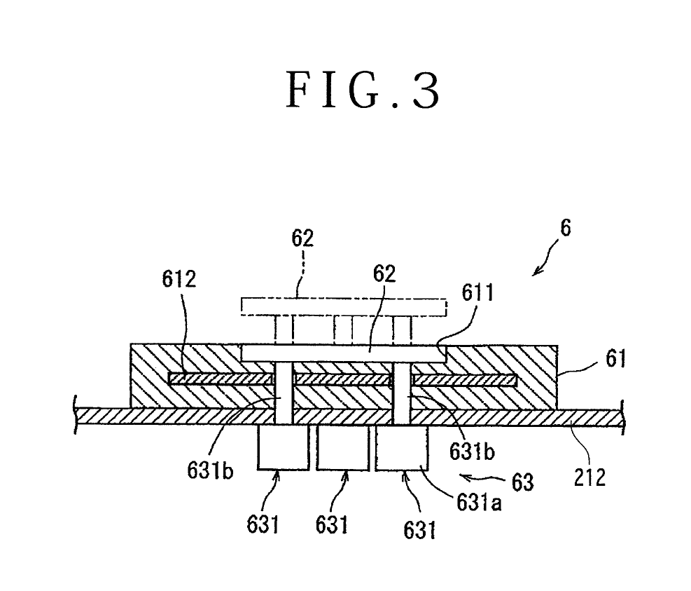

There is provided workpiece holding means 6 for holding a workpiece in the first vacuum chamber 21 of the housing 2. The workpiece holding means 6 includes a holding base 61, a center holding table 62 provided at a central portion of the holding base 61, and elevating means 63 for vertically moving the center holding table 62. The workpiece holding means 6 will now be described in more detail with reference to FIGS. 2 and 3. The holding base 61 constituting the workpiece holding means 6 is formed of a ceramic material in this preferred embodiment. A circular recess 611 for receiving the center holding table 62 is formed on the upper surface of the holding base 61 at its central portion. As shown in FIG. 1, the holding base 61 is provided on a bottom wall 212 forming the first vacuum chamber 21 of the housing 2. As shown in FIG. 3, the holding base 61 is provided with an electrode 612 for generating electric charges by the application of electric power thereto. The electrode 612 is connected to DC voltage applying means 613 (see FIG. 1). When a DC voltage is applied from the DC voltage applying means 613 to the electrode 612, a Coulomb force acts between the holding base 61 and the workpiece, so that the holding base 61 functions as an electrostatic chuck for electrostatically holding the workpiece by using this Coulomb force.

The center holding table 62 constituting the workpiece holding means 6 is formed of a ceramic material in this preferred embodiment. The center holding table 62 has a diameter slightly smaller than that of the circular recess 611 of the holding base 61 and has a thickness substantially equal to the depth of the circular recess 611. The elevating means 63 includes three air cylinder mechanisms 631. Each air cylinder mechanism 631 is composed of an air cylinder 631a and a piston rod 631b connected to a piston (not shown) provided in the air cylinder 631a. Each air cylinder 631a is mounted on the bottom wall 212 forming the first vacuum chamber 21 of the housing 2, and each piston rod 631b is inserted through a communication hole formed in the bottom wall 212 and the holding base 61. The front end (upper end as viewed in FIG. 3) of each piston rod 631b is connected to the lower surface of the center holding table 62.

Each air cylinder 631a has an operating chamber (not shown). The operating chambers of the air cylinders 631a of the three air cylinder mechanisms 631 are adapted to communicate through an electromagnetic three-way valve 632 to a vacuum source 633. The elevating means 63 configured above operates in the following manner. When the operating chambers of the air cylinders 631a are exposed through the electromagnetic three-way valve 632 to the atmosphere, the piston rods 631b are pushed up in the condition where the first vacuum chamber 21 is evacuated, so that the center holding table 62 is set at a standby position (upper position) (the position shown by a solid line in FIG. 2, or the position shown by a phantom line in FIGS. 1 and 3). Conversely, when the operating chambers of the air cylinders 631a are in communication with the vacuum source 633 through the electromagnetic three-way valve 632, the piston rods 631b are pushed down in the condition where the first vacuum chamber 21 is evacuated, so that the center holding table 62 is set at a working position (lower position) (the position shown by a solid line in FIG. 3).

The plasma etching apparatus 1 further includes plasma generation gas discharging means 7 as processing means for processing the workpiece held by the workpiece holding means 6. The plasma generation gas discharging means 7 is provided in the first vacuum chamber 21 of the housing 2. More specifically, the plasma generation gas discharging means 7 is provided above the workpiece holding means 6 so as to be opposed thereto, and functions to discharge a plasma generation mixture gas composed mainly of helium (He) and a fluoride gas such as SF₆, CF₄, and C₂F₆.

Referring again to FIG. 1, temporary placing means 8 for temporarily placing the workpiece is provided in the second vacuum chamber 22 of the housing 2 at a position near the workpiece load/unload opening 221a. The temporary placing means 8 is composed of a support base 81 provided on a bottom wall 223 forming the second vacuum chamber 22 of the housing 2 and a temporary placing table 82 provided on the support base 81. The temporary placing table 82 has a diameter equal to that of the center holding table 62 constituting the workpiece holding means 6.

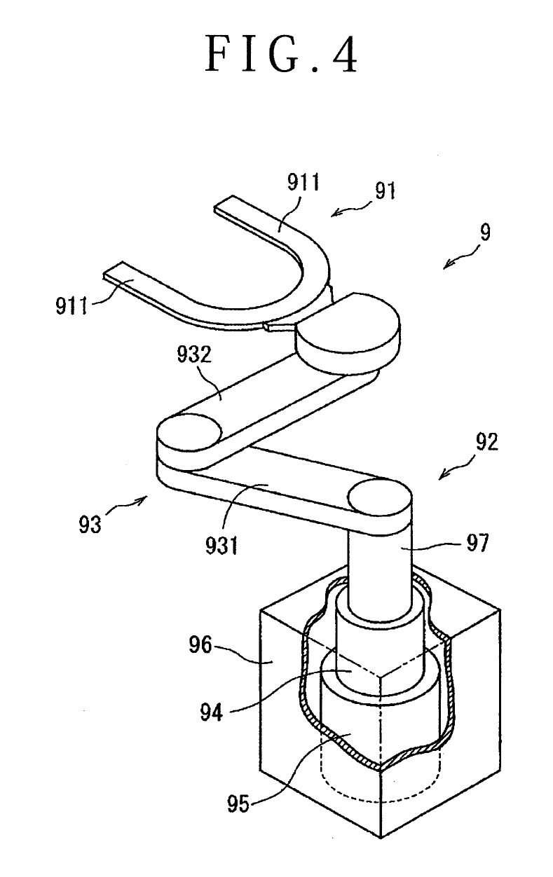

The plasma etching apparatus 1 further includes workpiece handling means 9 provided between the temporary placing means 8 and the partition wall 23 in the second vacuum chamber 22 of the housing 2. This workpiece handling means 9 will now be described with reference to FIG. 4. As shown in FIG. 4, the workpiece handling means 9 includes a periphery supporting member 91 having two supporting portions 911 for supporting a peripheral portion of a workpiece to be hereinafter described and a transfer mechanism 92 for moving the periphery supporting member 91 to a predetermined position. The two supporting portions 911 of the periphery supporting member 91 are formed from a thin plate member having a forked shape such that the two supporting portions 911 are spaced from each other. The space between the two supporting portions 911 is set larger than the diameter of the center holding table 62. The transfer mechanism 92 includes an arm mechanism 93 for supporting the periphery supporting member 91, an elevating mechanism 94 for vertically moving the arm mechanism 93, and a rotating mechanism 95 for rotating the arm mechanism 93.

The arm mechanism 93 is composed of a first arm 931 and a second arm 932 pivotably connected to the first arm 931. The periphery supporting member 91 is pivotably mounted to the second arm 932 of the arm mechanism 93. The first arm 931 of the arm mechanism 93 is mounted to an operating shaft 97. The operating shaft 97 is supported to a case 96 so as to be rotatable and vertically movable. That is, the operating shaft 97 is vertically movable by the elevating mechanism 94 and rotatable by the rotating mechanism 95. The elevating mechanism 94 includes a reversible motor and a screw mechanism to be driven by this reversible motor. When the reversible motor of the elevating mechanism 94 is operated in a normal direction, the operating shaft 97 is raised by the screw mechanism, whereas when the reversible motor of the elevating mechanism 94 is operated in a reverse direction, the operating shaft 97 is lowered by the screw mechanism. The rotating mechanism 95 includes a reversible motor and a drive mechanism to be driven by this reversible motor. When the reversible motor of the rotating mechanism 95 is operated in a normal direction, the operating shaft 97 is rotated in one direction by the drive mechanism, whereas when the reversible motor of the rotating mechanism 95 is operated in a reverse direction, the operating shaft 97 is rotated in the other direction by the drive mechanism.

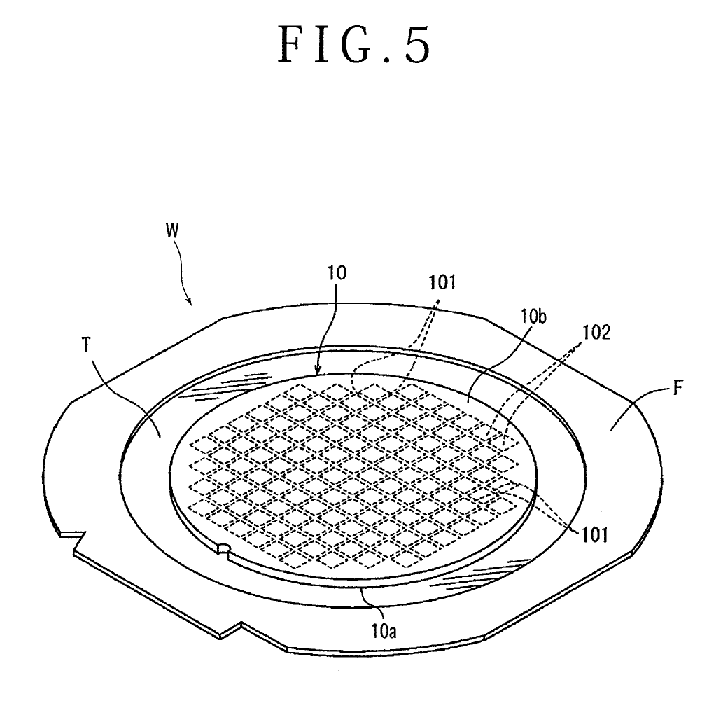

There will now be described a process of plasma-etching the back side of a semiconductor wafer as a workpiece by using the plasma etching apparatus 1 configured above. FIG. 5 shows a semiconductor wafer 10 as a workpiece to be processed by the plasma etching apparatus 1. The semiconductor wafer 10 shown in FIG. 5 is a disk-shaped silicon wafer having a front side 10a and a back side 10b. A plurality of crossing streets 101 are formed on the front side 10a of the semiconductor wafer 10 to thereby partition a plurality of regions where a plurality of devices 102 are respectively formed. The back side 10b of the semiconductor wafer 10 has already been ground to reduce the thickness of the semiconductor wafer 10 to a predetermined thickness (e.g., 100 μm). The front side 10a of the semiconductor wafer 10 is attached to a dicing tape T supported to an annular frame F. The dicing tape T is supported at its peripheral portion to the annular frame F in such a manner as to close the inside opening of the annular frame F. Accordingly, the back side 10b of the semiconductor wafer 10 attached to the dicing tape T is oriented upward as shown in FIG. 5. In the following description, the unit of the semiconductor wafer 10, the dicing tape T, and the annular frame F will be referred to as a workpiece W.

In performing plasma etching to the semiconductor wafer 10 of the workpiece W, the shutter 31 of the shutter means 3 is set to the open position shown by the solid line in FIG. 1 and the gate 41 of the gate means 4 is also set to the open position shown by the solid line in FIG. 1. Thereafter, the workpiece W is loaded through the workpiece load/unload opening 221a into the second vacuum chamber 22 by workpiece loading/unloading means (not shown) and the semiconductor wafer 10 as a central area of the workpiece W is placed on the temporary placing table 82 of the temporary placing means 8. After thus loading the workpiece W to the temporary placing means 8, the gate 41 of the gate means 4 is set to the closed position shown by the phantom line in FIG. 1.

Thereafter, the transfer mechanism 92 of the workpiece handling means 9 is operated to insert the two supporting portions 911 of the periphery supporting member 91 into the space below the workpiece W placed on the temporary placing table 82 of the temporary placing means 8 and next to raise the two supporting portions 911, thereby supporting the annular frame F as a peripheral area of the workpiece W on the two supporting portions 911. Thereafter, the workpiece W supported on the two supporting portions 911 of the periphery supporting member 91 is loaded through the communication opening 231 of the partition wall 23 into the first vacuum chamber 21 by the transfer mechanism 92, and the semiconductor wafer 10 as the central area of the workpiece W is placed on the center holding table 62 of the workpiece holding means 6. After thus loading the workpiece W to the center holding table 62 of the workpiece holding means 6, the periphery supporting member 91 of the workpiece handling means 9 is returned to the position shown in FIG. 1, and the shutter 31 of the shutter means 3 is set to the closed position shown by the phantom line in FIG. 1. Thereafter, the elevating means 63 of the workpiece holding means 6 is operated to set the center holding table 62 to the working position (the lower position shown by the solid line in FIG. 3), and the DC voltage applying means 613 is operated to apply a DC voltage to the electrode 612, thereby making the center holding table 62 function as an electrostatic chuck for electrostatically holding the workpiece W by using a Coulomb force.

After electrostatically holding the workpiece W by using a Coulomb force generated by the workpiece holding means 6, the plasma generation gas discharging means 7 as the processing means for processing the semiconductor wafer 10 of the workpiece W held by the workpiece holding means 6 is operated to discharge a mixture gas for generation of a plasma toward the back side 10b (upper surface) of the semiconductor wafer 10 of the workpiece W held by the workpiece holding means 6. Further, the first evacuating means 51 is operated to evacuate the first vacuum chamber 21 to about 20 Pa, for example. Thereafter, RF power is applied to the workpiece holding means 6 and the plasma generation gas discharging means 7. As a result, a plasma is generated in the space between the workpiece holding means 6 and the plasma generation gas discharging means 7, and an active substance due to this plasma acts on the back side 10b (upper surface) of the semiconductor wafer 10, thereby etching the back side 10b to remove a grinding strain left on the back side 10b (plasma etching step).

After performing the plasma etching step mentioned above, the processed workpiece W is unloaded from the workpiece holding means 6 in the following manner. During the plasma etching step, the second evacuating means 52 is operated to evacuate the second vacuum chamber 22. Prior to unloading the processed workpiece W from the workpiece holding means 6, the application of the DC voltage to the electrode 612 by the DC voltage applying means 613 is canceled and the electromagnetic three-way valve 632 of the elevating means 63 is operated to expose the operating chambers of the air cylinders 631a to the atmosphere. As a result, the atmospheric air enters the operating chambers of the air cylinders 631a to raise the piston rods 631b because the first vacuum chamber 21 is in the evacuated condition. Accordingly, the center holding table 62 on which the semiconductor wafer 10 as the central area of the processed workpiece W is placed is set to the standby position (the upper position shown by the solid line in FIG. 2, or the upper position shown by the phantom line in FIGS. 1 and 3).

Thereafter, the shutter operating means 32 of the shutter means 3 is operated to move the shutter 31 upward to the open position shown by the solid line in FIG. 1. Accordingly, the communication opening 231 of the partition wall 23 is exposed to make the communication between the first vacuum chamber 21 and the second vacuum chamber 22. In the condition where the communication opening 231 of the partition wall 23 is exposed, the transfer mechanism 92 of the workpiece handling means 9 is operated to move the periphery supporting member 91 from the second vacuum chamber 22 through the communication opening 231 to the first vacuum chamber 21 and next to insert the two supporting portions 911 of the periphery supporting member 91 into the space below the processed workpiece W placed on the center holding table 62 of the workpiece holding means 6. Thereafter, the periphery supporting member 91 is raised to support the annular frame F as the peripheral area of the processed workpiece W on the two supporting portions 911.

Thereafter, the processed workpiece W supported on the two supporting portions 911 of the periphery supporting member 91 is transferred from the first vacuum chamber 21 through the communication opening 231 of the partition wall 23 to the second vacuum chamber 22 by the transfer mechanism 92, and the semiconductor wafer 10 as the central area of the processed workpiece W is placed on the temporary placing table 92 of the temporary placing means 8. After thus transferring the processed workpiece W to the temporary placing table 82 of the temporary placing means 8, the periphery supporting member 91 of the workpiece handling means 9 is returned to the position shown in FIG. 1. Although the communication opening 231 of the partition wall 23 is exposed to the second vacuum chamber 22 in unloading the processed workpiece W from the first vacuum chamber 21 to the second vacuum chamber 22, the pressure in the first vacuum chamber 21 does not become an atmospheric pressure because the second vacuum chamber 22 is in the evacuated condition.

After placing the processed workpiece W on the temporary placing table 82 of the temporary placing means 8 as mentioned above, the shutter 31 of the shutter means 3 is set to the closed position shown by the phantom line in FIG. 1. Thereafter, the gate 41 of the gate means 4 is set to the open position shown by the solid line in FIG. 1. As a result, the pressure in the second vacuum chamber 22 becomes an atmospheric pressure. However, the first vacuum chamber 21 is maintained in the evacuated condition because the shutter 31 of the shutter means 3 is set in the closed position shown by the phantom line in FIG. 1.

Thereafter, the workpiece loading/unloading means (not shown) is inserted through the workpiece load/unload opening 221a into the second vacuum chamber 22 to hold the processed workpiece W placed on the temporary placing table 82 of the temporary placing means 8 and then unload the processed workpiece W from the second vacuum chamber 22 through the workpiece load/unload opening 221a.

Thereafter, another workpiece W to be processed is similarly loaded through the workpiece load/unload opening 221a into the second vacuum chamber 22 by the workpiece loading/unloading means (not shown), and the semiconductor wafer 10 as the central area of this workpiece W to be processed is placed on the temporary placing table 82 of the temporary placing means 8. After thus placing the workpiece W to be processed on the temporary placing table 82, the gate 41 of the gate means 4 is set to the closed position shown by the phantom line in FIG. 1. Thereafter, the second evacuating means 52 is operated to evacuate the second vacuum chamber 22.

After evacuating the second vacuum chamber 22 in which the workpiece W to be processed is loaded, the shutter operating means 32 of the shutter means 3 is operated to move the shutter 31 upward, thereby setting the shutter 31 to the open position shown by the solid line in FIG. 1. Accordingly, the communication opening 231 of the partition wall 23 is exposed to make the communication between the first vacuum chamber 21 and the second vacuum chamber 22. In the condition where the communication opening 231 of the partition wall 23 is exposed, the transfer mechanism 92 of the workpiece handling means 9 is operated to insert the two supporting portions 911 of the periphery supporting member 91 into the space below the workpiece W placed on the temporary placing table 82 of the temporary placing means 8 and next to raise the two supporting portions 911, thereby supporting the annular frame F as the peripheral area of the workpiece W on the two supporting portions 911. Thereafter, the workpiece W supported on the two supporting portions 911 of the periphery supporting member 91 is loaded through the communication opening 231 of the partition wall 23 into the first vacuum chamber 21 by the transfer mechanism 92, and the semiconductor wafer 10 as the central area of the workpiece W is placed on the center holding table 62 of the workpiece holding means 6. After thus loading the workpiece W to be processed to the central holding table 62 of the workpiece holding means 6, the workpiece handling means 9 is returned to the position shown in FIG. 1, and the shutter 31 of the shutter means 3 is set to the closed position shown by the phantom line in FIG. 1. Although the communication opening 231 of the partition wall 23 is exposed to the second vacuum chamber 22 in loading the workpiece W from the second vacuum chamber 22 to the first vacuum chamber 21, the pressure in the first vacuum chamber 21 does not become an atmospheric pressure because the second vacuum chamber 22 is in the evacuated condition.

Thereafter, the workpiece W placed on the center holding table 62 of the workpiece holding means 6 is electrostatically held by using a Coulomb force as mentioned above to perform the plasma etching step. This plasma etching step is performed under vacuum in the first vacuum chamber 21. Since the first vacuum chamber 21 is maintained in the evacuated condition, the plasma etching step as vacuum processing can be performed at once, thereby improving the productivity. After performing the plasma etching step, the various steps mentioned above are performed to unload the processed workpiece W from the plasma etching apparatus 1. While the present invention is applied to the plasma etching apparatus 1 in the above preferred embodiment, the present invention is applicable widely to any vacuum processing apparatus for processing a workpiece in the condition where a processing chamber is evacuated.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A vacuum processing apparatus for processing a workpiece under vacuum, comprising:
a housing having a first vacuum chamber for processing said workpiece and a second vacuum chamber partitioned from said first vacuum chamber by a partition wall and communicating with said first vacuum chamber through a communication opening formed in said partition wall;
shutter means for closing said communication opening of said partition wall;
gate means for closing a workpiece load/unload opening formed in a side wall of said housing and communicating with said second vacuum chamber;
workpiece holding means provided in said first vacuum chamber for holding said workpiece;
processing means for processing said workpiece held by said workpiece holding means;
first evacuating means for evacuating said first vacuum chamber;
second evacuating means for evacuating said second vacuum chamber;
temporary placing means provided in said second vacuum chamber for temporarily placing said workpiece; and
workpiece handling means for transferring said workpiece placed on said temporary placing means through said communication opening of said partition wall to said workpiece holding means provided in said first vacuum chamber and also for transferring said workpiece placed on said workpiece holding means through said communication opening of said partition wall to said temporary placing means;
said workpiece holding means having a center holding table for holding a central area of said workpiece and elevating means for vertically moving said center holding table;
said workpiece handling means having a periphery supporting member for supporting a peripheral area of said workpiece.

2. The vacuum processing apparatus according to claim 1, wherein said periphery supporting member of said workpiece handling means has two supporting portions for supporting said peripheral area of said workpiece, said two supporting portions being spaced a distance larger than the size of said center holding table.

3. The vacuum processing apparatus according to claim 2, wherein said workpiece is a semiconductor wafer supported through a dicing tape to an annular frame, said center holding table holding said semiconductor wafer as said central area of said workpiece, said two supporting portions of said periphery supporting member supporting said annular frame as said peripheral area of said workpiece.
